(19) United States
(12) Patent Application Publication
(10) Pub. No.: US 2016/0111514 A1
(43) Pub. Date: Apr. 21, 2016

(54) ULTRA-LOW RESISTANCE GATE STRUCTURE FOR NON-PLANAR DEVICE VIA MINIMIZED WORK FUNCTION MATERIAL

(71) Applicant: GLOBALFOUNDRIES Inc., Grand Cayman (KY)

(72) Inventor: Hui ZANG, Guilderland, NY (US)

(73) Assignee: GLOBALFOUNDRIES INC., Grand Cayman (KY)

(21) Appl. No.: 14/515,141

(22) Filed: Oct. 15, 2014

(51) Int. Cl. H01L 29/49; H01L 29/78; H01L 29/66

(52) U.S. Cl. CPC H01L 29/4958; H01L 29/66795; H01L 29/66545; H01L 29/7851

(57) ABSTRACT

A non-planar semiconductor structure includes an ultra-low resistance gate structure. The non-planar structure includes a semiconductor substrate and raised semiconductor structures coupled to the substrate, a lower portion of the raised structures surrounded by a layer of isolation material. The structure further includes gate structures surrounding an upper portion of the raised structures, the gate structures including a conductive material and a layer of work function material present only in a limited area surrounding each raised structure. The limited area of work function material is achieved in fabrication by including dummy gate structures covering a layer of selectively removable material above the raised structures and a layer of hard mask material above the selectively removable layer, removing the selectively removable layer with the dummy gate structures, filling the resulting gate openings with work function material and then removing most of it, using the layer of hard mask material to delimit the limited area of work function material.

### BACKGROUND OF THE INVENTION

1. Technical Field

The present invention generally relates to gate structures for semiconductor devices. More particularly, the present invention relates to reduced resistance gate structures for non-planar semiconductor devices by minimizing the amount of work function material included in the final gate structure.

2. Background Information

Currently, gate structures for non-planar semiconductor devices include n-type and/or p-type work function metal to achieve a desired performance. While the use of work function metal has advanced semiconductor fabrication, the materials have an inherently high resistance. The tools used to apply the work function metal have improved to achieve even coverage, but the amount of work function metal applied can result in pinch-off, i.e., the work function metal along the sides of the gate openings merging at the top and leaving no room for conductive gate metal. In other words, the even coverage has come at the cost of over coverage.

Thus, a need exists to reduce or eliminate the occurrence of pinch-off, with a resulting reduction in gate resistance.

### SUMMARY OF THE INVENTION

The shortcomings of the prior art are overcome and additional advantages are provided through the provision, in one aspect, of a method of reducing gate resistance in a non-planar semiconductor structure. The method includes providing a starting non-planar semiconductor structure, the starting structure including a semiconductor substrate, at least one raised semiconductor structure coupled to the substrate, and at least one dummy gate structure covering a portion of the at least one raised structure. The method further includes creating spacers adjacent the at least one dummy gate structure, removing the at least one dummy gate structure, the removing creating at least one gate opening between the spacers, creating a layer of at least one work function material in the at least one gate opening in a delimited area immediately surrounding each raised structure, and filling the at least one gate opening with at least one conductive material.

In accordance with another aspect, a non-planar semiconductor structure is provided. The structure includes a semiconductor substrate, and at least one raised semiconductor structure coupled to the substrate, a lower portion of the at least one raised structure surrounded by a layer of isolation material. The structure further includes at least one gate structure surrounding an upper portion of the at least one raised semiconductor structure, the at least one gate structure including a conductive material and a layer of at least one work function material present only in a limited area surrounding the at least one raised structure.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting non-planar semiconductor structure, the structure including a bulk semiconductor substrate, one or more raised semiconductor structures coupled to the substrate, a layer of dielectric material covering the raised structure(s), a layer of selectively removable material over the dielectric layer, and a layer of hard mask material over the selectively removable layer, in accordance with one or more aspects of the present invention.

FIG. 2 depicts one example of the non-planar structure of FIG. 1 after creating a conformal blanket layer of an isolation material over the starting structure, and then planarizing the isolation layer, stopping on the hard mask layer above the raised structure(s), in accordance with one or more aspects of the present invention.

FIG. 3 depicts one example of the non-planar structure of FIG. 2 after recessing the planarized dielectric layer to expose the hard mask layer, in accordance with one or more aspects of the present invention.

FIG. 4 depicts one example of the non-planar structure of FIG. 3 after creating spacers adjacent the exposed layer of hard mask material above the raised structure(s), in accordance with one or more aspects of the present invention.

FIG. 5 depicts one example of the non-planar structure of FIG. 4 after etching (e.g., via wet etch) the layer of isolation material selective to the layer of hard mask material and spacers, in accordance with one or more aspects of the present invention.

FIG. 6 depicts one example of the non-planar structure of FIG. 5 after removing the remaining isolation material along sides of the raised structure(s) under the spacers, in accordance with one or more aspects of the present invention.

FIG. 7 depicts one example of the non-planar structure of FIG. 6 after creating a thin layer of dielectric material along sides of the raised structure(s), e.g., by oxidation, in accordance with one or more aspects of the present invention.

FIG. 8 depicts another cross-sectional view of the non-planar structure of FIG. 7 taken across the structure in front of a raised structure (i.e., a y-direction cut if looking top-down at structure) after creation of one or more dummy gate structures covering portion(s) of the raised structure(s), each dummy gate structure including a layer of a dummy gate material, a layer of hard mask material over the layer of dummy gate material and a layer of dielectric material over the layer of hard mask material, in accordance with one or more aspects of the present invention.

FIG. 9 depicts one example of the non-planar structure of FIG. 8 after removal of the layer of hard mask material and the layer of selectively etchable material over exposed areas of the raised structure(s), i.e., areas not covered by the one or more dummy gate structures, in accordance with one or more aspects of the present invention.

FIG. 10 depicts one example of the non-planar structure of FIG. 9 after creation of spacers adjacent each dummy gate structure, in accordance with one or more aspects of the present invention.

FIG. 11 depicts one example of the non-planar structure of FIG. 10 after removal of the layer of dielectric material and recessing of exposed areas of the raised structure(s) adjacent to the spacers for the one or more dummy gate structures, for example, using a reactive ion etch, and creation of epitaxial material (n-type and/or p-type) in the recessed areas, e.g., by growing epitaxial structures, in accordance with one or more aspects of the present invention.

FIG. 12 depicts one example of the non-planar structure of FIG. 11 after creation of a conformal blanket layer of dielectric material over the structure and planarizing using, for example, the layer of hard mask material in the dummy gate structure(s) as a stop, in accordance with one or more aspects of the present invention.

FIG. 13 depicts one example of the non-planar structure of FIG. 12 after removal of the dummy gate structure(s), creating gate opening(s) between the spacers, and removal of the remaining layer of selectively etchable material, in accordance with one or more aspects of the present invention.

FIG. 14 depicts one example of the non-planar structure of FIG. 13 after partially filling the gate opening(s) with work function material(s), in accordance with one or more aspects of the present invention.

FIG. 15 depicts another view of the non-planar structure of FIG. 14, a cross-sectional view taken through the work function material in one of the gate opening(s), in accordance with one or more aspects of the present invention.

FIG. 16 depicts one example of the non-planar structure of FIG. 15 after removal of the work function material everywhere except an area delimited by the layer of hard mask material over the raised structure(s), in accordance with one or more aspects of the present invention.

FIG. 17 depicts one example of the non-planar structure of FIG. 16 after removal of the layer of hard mask material over the raised structure(s), in accordance with one or more aspects of the present invention.

FIG. 18 depicts one example of the non-planar structure of FIG. 17 after filling the gate opening(s) with a conductive material, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

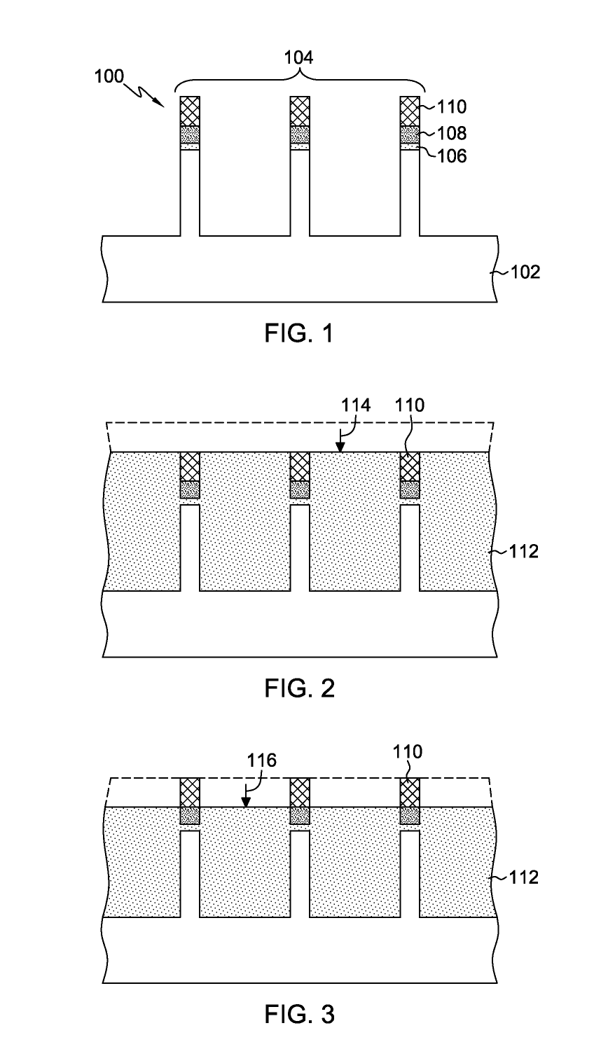

FIG. 1 is a cross-sectional view of one example of a starting non-planar semiconductor structure 100, the structure including a bulk semiconductor substrate 102, one or more raised semiconductor structures 104 coupled to the substrate, a layer 106 of dielectric material covering the raised structure(s), a layer 108 of selectively removable material over the dielectric layer, and a layer 110 of hard mask material over the selectively removable layer, in accordance with one or more aspects of the present invention.

The starting structure may be conventionally fabricated, for example, using known processes and techniques. However, it will be understood that the fabrication of the starting structure forms no part of the present invention. Further, although only a portion is shown for simplicity, it will be understood that, in practice, many such structures are typically included on the same bulk substrate.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

The non-planar structure further includes at least one raised semiconductor structure 104 (raised with respect to the substrate). In one example, the raised structures may take the form of a “fin.” The raised structure(s) may be etched from a bulk substrate, and may include, for example, any of the materials listed above with respect to the substrate. Further, some or all of the raised structure(s) may include added impurities (e.g., by doping), making them n-type or p-type. The structure further includes at least one gate structure 106 surrounding a portion of one or more of the raised structures.

FIG. 2 depicts one example of the non-planar structure of FIG. 1 after creating a conformal blanket layer 112 of an isolation material over the starting structure, and then planarizing 114 the isolation layer, stopping on the hard mask layer 110 above the raised structure(s), in accordance with one or more aspects of the present invention.

FIG. 3 depicts one example of the non-planar structure of FIG. 2 after recessing 116 the planarized dielectric layer 112 to expose the hard mask layer 110, in accordance with one or more aspects of the present invention.

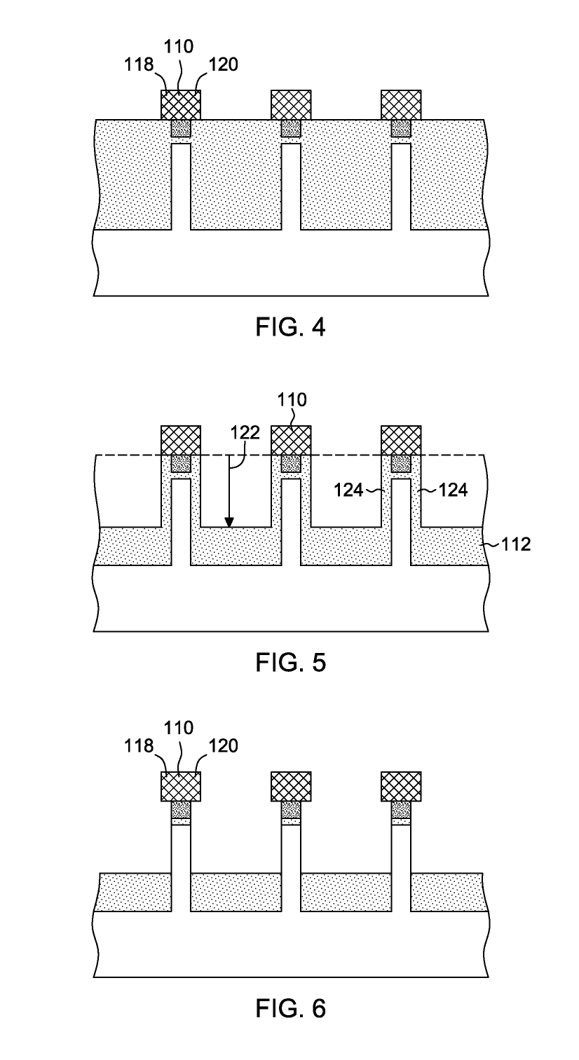

FIG. 4 depicts one example of the non-planar structure of FIG. 3 after creating spacers (e.g., spacers 118 and 120) adjacent the exposed layer 110 of hard mask material above the raised structure(s), in accordance with one or more aspects of the present invention.

In one example, the spacers may be created by creating a conformal layer of hard mask material (e.g., a same material as layer 110), for example, a conformal thin film deposition, followed by an etch, e.g., an anisotropic etch.

FIG. 5 depicts one example of the non-planar structure of FIG. 4 after etching 122 (e.g., via wet etch) the layer 112 of isolation material selective to the layer 110 of hard mask material and spacers, in accordance with one or more aspects of the present invention.

FIG. 6 depicts one example of the non-planar structure of FIG. 5 after removing the remaining isolation material (124, FIG. 5) along sides of the raised structure(s) under the spacers, e.g., spacers 118 and 120, in accordance with one or more aspects of the present invention.

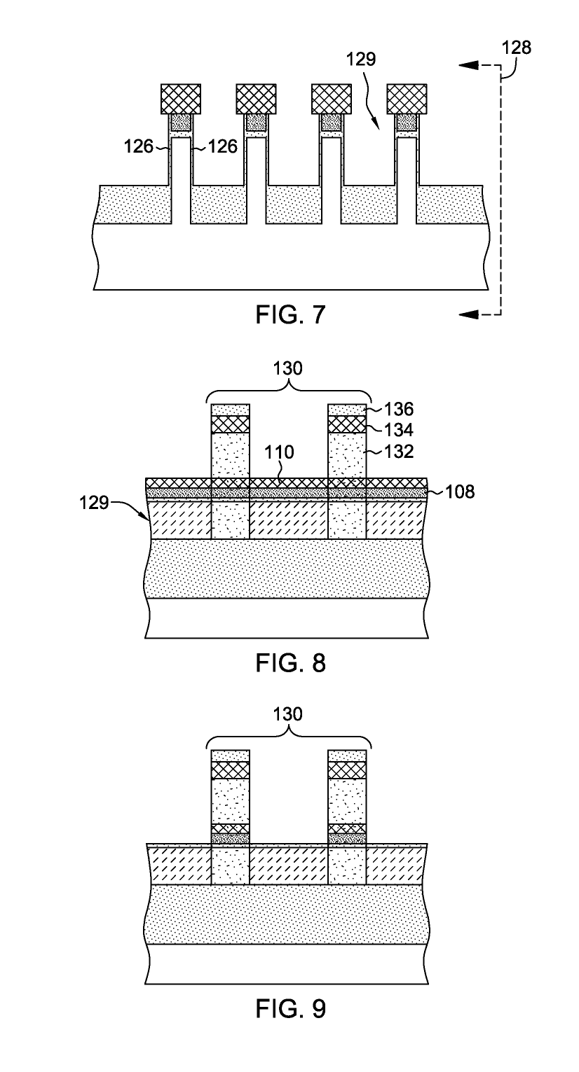

FIG. 7 depicts one example of the non-planar structure of FIG. 6 after creating a thin layer 126 of dielectric material (e.g., about 1 nm to about 6 nm thick) along sides of the raised structure(s), e.g., by oxidation, in accordance with one or more aspects of the present invention.

FIG. 8 depicts another cross-sectional view 128 of the non-planar structure of FIG. 7 taken across the non-planar structure in front of a raised structure (i.e., a y-direction cut if looking top-down at structure) (e.g., raised structure 129) after creation of one or more dummy gate structures 130 covering portion(s) of the raised structure(s), each dummy gate structure including a layer 132 of a dummy gate material, a layer 134 of hard mask material over the layer of dummy gate material and a layer 136 of dielectric material over the layer of hard mask material (also known as a “bi-layer hard mask”), in accordance with one or more aspects of the present invention.

It will be understood that in FIGS. 8-12, gate structures 130 actually cover portions of and obscure raised structure 129. However, the views of the gate structures are made partially “transparent” in order to show the raised structure thereunder for ease of understanding.

FIG. 9 depicts one example of the non-planar structure of FIG. 8 after removal of the layer (110, FIG. 8) of hard mask material and the layer (108, FIG. 8) of selectively etchable material over exposed areas of the raised structure(s) (104, FIG. 1), i.e., areas not covered by the one or more dummy gate structures 130, in accordance with one or more aspects of the present invention.

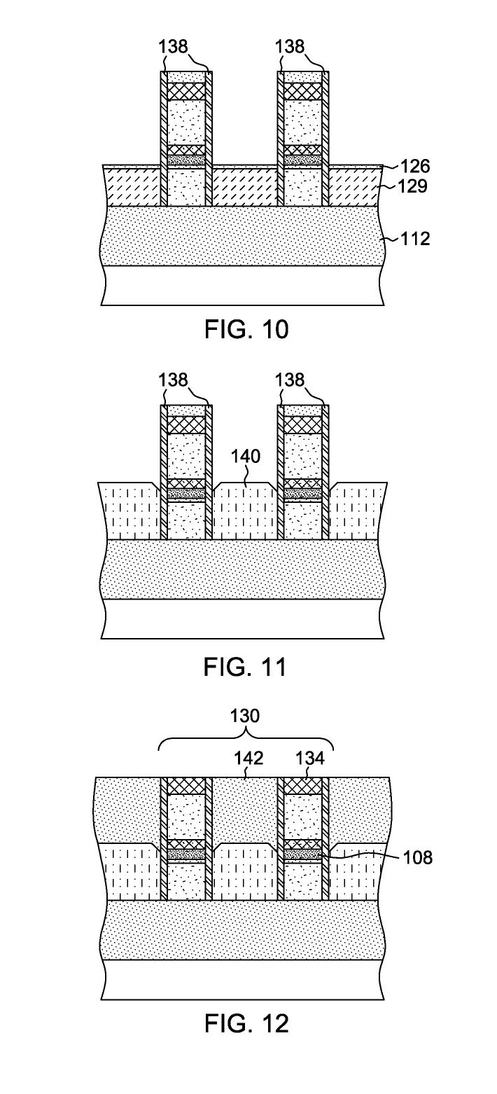

FIG. 10 depicts one example of the non-planar structure of FIG. 9 after creation of spacers 138 adjacent each dummy gate structure, in accordance with one or more aspects of the present invention. In one example, the spacer material includes a low-k spacer material, i.e., a dielectric constant (k) of about 6 k or less.

FIG. 11 depicts one example of the non-planar structure of FIG. 10 after removal of the layer 126 of dielectric material and recessing of exposed areas of the raised structure(s) (e.g., raised structure 129, FIG. 10) adjacent to the spacers for the one or more dummy gate structures, for example, using a reactive ion etch, and creation of epitaxial material 140 (n-type and/or p-type) in the recessed areas 138, e.g., by growing epitaxial structures, in accordance with one or more aspects of the present invention.

FIG. 12 depicts one example of the non-planar structure of FIG. 11 after creation of a conformal blanket layer 142 of dielectric material over the structure and planarizing using, for example, the layer 134 of hard mask material in the dummy gate structure(s) as a stop, in accordance with one or more aspects of the present invention.

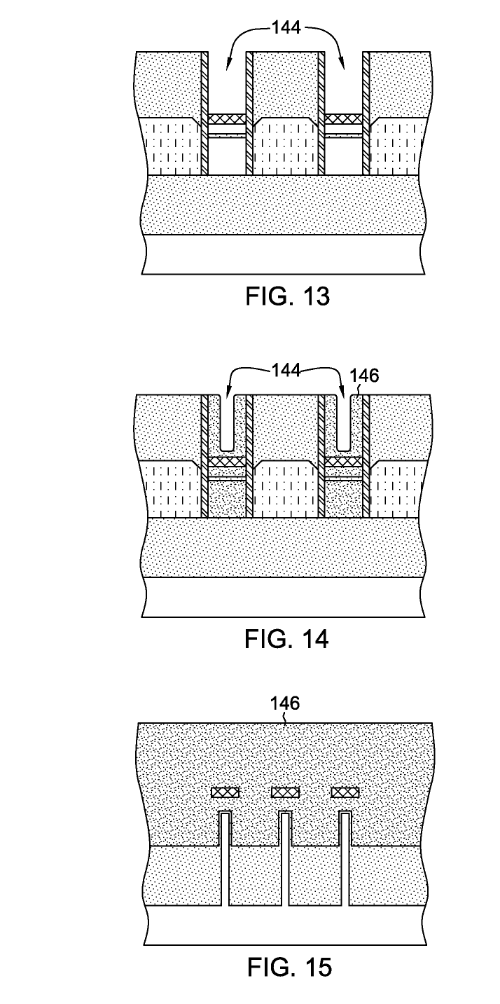

FIG. 13 depicts one example of the non-planar structure of FIG. 12 after removal of the dummy gate structure(s) (130, FIG. 12), creating gate opening(s) 144 between the spacers, and removal of the remaining layer (108, FIG. 12) of selectively etchable material, in accordance with one or more aspects of the present invention.

FIG. 14 depicts one example of the non-planar structure of FIG. 13 after partially filling the gate opening(s) 144 with work function material(s) 146, in accordance with one or more aspects of the present invention.

FIG. 15 depicts another view of the non-planar structure of FIG. 14, a cross-sectional view taken through the work function material 146 in a gate opening 144, in accordance with one or more aspects of the present invention.

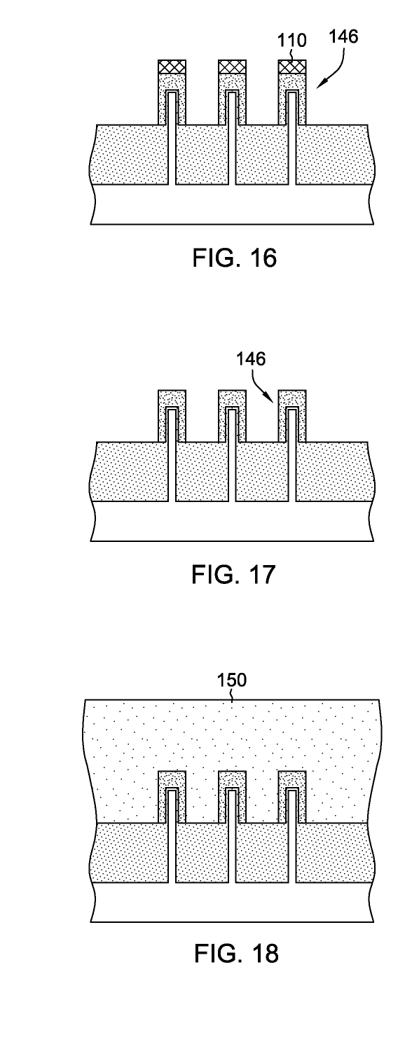

FIG. 16 depicts one example of the non-planar structure of FIG. 15 after removal of the work function material (146, FIG. 15) everywhere except an area 148 delimited by the layer 110 of hard mask material over the raised structure(s), in accordance with one or more aspects of the present invention.

Although FIGS. 16-18 show the case of a single type (n-type or p-type) structure, it will be understood that both types could be included on the same bulk substrate (e.g., p-type transistors and n-type transistors). For example, if we assume work function material 146 is a p-type work function material, and there is a similar structure for a n-type device, additional processes of removing the p-type work function material from the n-type device structure and creating/removal of n-type work function in a manner similar to FIGS. 14 and 15 would be performed, resulting in both types of structures, each having the relevant type of work function material.

FIG. 17 depicts one example of the non-planar structure of FIG. 16 after removal of the layer (110, FIG. 16) of hard mask material over the raised structure(s), in accordance with one or more aspects of the present invention.

FIG. 18 depicts one example of the non-planar structure of FIG. 17 after filling the gate opening(s) (144, FIG. 13) with a conductive material 150, in accordance with one or more aspects of the present invention.

In a first aspect, disclosed above is a method of reducing gate resistance in a non-planar semiconductor structure. The method includes providing a starting non-planar semiconductor structure, the starting structure including a semiconductor substrate, raised semiconductor structure(s) coupled to the substrate, and dummy gate structure(s) covering a portion of the raised structure(s). The method further includes creating spacers adjacent the dummy gate structure(s), removing the dummy gate structure(s), the removing creating gate opening(s) between the spacers, creating a layer of work function material(s) in the gate opening(s) in a delimited area immediately surrounding each raised structure, and filling the gate opening(s) with conductive material(s).

In one example, creating the layer of work function material(s) may include, for example, creating a layer of selectively removable material over the raised structure(s) and a layer of hard mask material over the layer of selectively removable material, the dummy gate structure(s) also covering the layer of selectively removable material and the layer of hard mask material over the portion of the raised structure(s), removing the layer of hard mask material and the layer of selectively removable material over exposed portions of the raised structure(s), and removing a remainder of the layer of selectively removable material under the dummy gate structure(s) after removing the dummy gate structure(s). The layer of work function material(s) is delimited by a remainder of the layer of hard mask material, and the method may further include, for example, removing the remainder of the layer of hard mask material prior to the filling.

Where creating the layer of work function material(s) includes the above, providing the starting non-planar structure may include, for example, providing a bulk semiconductor structure, the structure including a bulk semiconductor substrate, a layer of selectively removable material over the substrate, and a layer of the hard mask material over the layer of selectively removable material. Further, creating the layer of selectively removable material and the layer of hard mask material may include, for example, etching the bulk semiconductor structure to create the raised structure(s), and creating the dummy gate structure(s) covering the portion of the raised structure(s). In one example, the bulk semiconductor structure may further include, for example, a layer of dielectric material between the substrate and the layer of selectively removable material. In another example, the selectively removable material may include, for example, a selectively wet etchable material.

Where the layer of work function material(s) is delimited by the remainder of the layer of hard mask material, the method may further include, for example, prior to creating the spacers, creating a layer of isolation material surrounding the raised structure(s) and the layer of selectively removable material, and, after creating the spacers, recessing the layer of isolation material to surround only a bottom portion of the raised structure(s).

Where the layer of work function material(s) is delimited by the remainder of the layer of hard mask material, creating the layer of work function material(s) may include, for example, filling the gate opening(s) with the work function material(s), and removing the work function material(s) everywhere except under the layer of hard mask material over the raised structure(s).

The method of the first aspect may further include, for example, prior to removing the dummy gate structure(s), creating source and drain regions adjacent the spacers. In one example, the method may further include, for example, prior to creating the source and drain regions, recessing the exposed portions of the raised structure(s), creating the source and drain regions including, for example, creating epitaxial material in the recessed exposed portions. Where the epitaxial material is included, the method may further include, for example, after creating the source and drain regions and before removing the dummy gate structure(s), filling an area above the source and drain regions and between adjacent gate spacers with a dielectric material.

In a second aspect, disclosed above is a non-planar semiconductor structure. The structure includes a semiconductor substrate and raised semiconductor structure(s) coupled to the substrate, a lower portion of the raised structure(s) surrounded by a layer of isolation material. The structure further includes gate structure(s) surrounding an upper portion of the raised semiconductor structure(s), the gate structure(s) including a conductive material and a layer of work function material(s) present only in a limited area surrounding the raised structure(s).

In one example, a thickness of the layer of work function material(s) in the non-planar structure of the second aspect may be about 1 nm to about 8 nm (typically about 5 nm).

In one example, the layer of work function material(s) in the non-planar structure of the second aspect may include, for example, one or more p-type work function metals.

In another example, the layer of work function material(s) in the non-planar structure of the second aspect may include, for example, one or more n-type work function metals.

In one example, the raised structure(s) in the non-planar structure of the second aspect may include, for example, first raised structure(s) and second raised structure(s), the layer of work function material(s) including p-type work function metal(s) for the first raised structure(s) and n-type work function metal(s) for the second raised structure(s).

In one example, the conductive material in the non-planar structure of the second aspect may include, for example, a metal (e.g., one of tungsten, aluminum or other low-resistance and chemically stable metal).

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting non-planar semiconductor structure, the starting structure comprising a semiconductor substrate, at least one raised semiconductor structure coupled to the substrate, and at least one dummy gate structure covering a portion of the at least one raised structure;
creating spacers adjacent the at least one dummy gate structure;
removing the at least one dummy gate structure, the removing creating at least one gate opening between the spacers;
creating a layer of at least one work function material in the at least one gate opening in a delimited area immediately surrounding each raised structure; and
filling the at least one gate opening with at least one conductive material.

2. The method of claim 1, wherein creating the layer of at least one work function material comprises:
creating a layer of selectively removable material over the at least one raised structure and a layer of hard mask material over the layer of selectively removable material, wherein the at least one dummy gate structure also covers the layer of selectively removable material and the layer of hard mask material over the portion of the at least one raised structure;
removing the layer of hard mask material and the layer of selectively removable material over exposed portions of the at least one raised structure; and
removing a remainder of the layer of selectively removable material under the at least one dummy gate structure after removing the at least one dummy gate structure;
wherein the layer of at least one work function material is delimited by a remainder of the layer of hard mask material; and
wherein the method further comprises removing the remainder of the layer of hard mask material prior to the filling.

3. The method of claim 2, wherein providing the starting non-planar structure comprises providing a bulk semiconductor structure, the structure comprising a bulk semiconductor substrate, a layer of selectively removable material over the substrate, and a layer of the hard mask material over the layer of selectively removable material, and wherein creating the layer of selectively removable material and the layer of hard mask material comprises:
etching the bulk semiconductor structure to create the at least one raised structure; and
creating the at least one dummy gate structure covering the portion of the at least one raised structure.

4. The method of claim 3, wherein the bulk semiconductor structure further comprises a layer of dielectric material between the substrate and the layer of selectively removable material.

5. The method of claim 3, wherein the selectively removable material comprises a selectively wet etchable material.

6. The method of claim 2, further comprising:
prior to creating the spacers, creating a layer of isolation material surrounding the at least one raised structure and the layer of selectively removable material; and
after creating the spacers, recessing the layer of isolation material to surround only a bottom portion of the at least one raised structure.

7. The method of claim 2, wherein creating the layer of at least one work function material comprises:
filling the at least one gate opening with the at least one work function material; and
removing the at least one work function material everywhere except under the layer of hard mask material over the at least one raised structure.

8. The method of claim 1, further comprising, prior to removing the at least one dummy gate structure, creating source and drain regions adjacent the spacers.

9. The method of claim 8, further comprising, prior to creating the source and drain regions, recessing the exposed portions of the at least one raised structure, wherein creating the source and drain regions comprises creating epitaxial material in the recessed exposed portions.

10. The method of claim 9, further comprising, after creating the source and drain regions and before removing the at least one dummy gate structure, filling an area above the source and drain regions and between adjacent gate spacers with a dielectric material.

11. A non-planar semiconductor structure, comprising:
a semiconductor substrate;
at least one raised semiconductor structure coupled to the substrate, a lower portion of the at least one raised structure surrounded by a layer of isolation material; and
at least one gate structure surrounding an upper portion of the at least one raised semiconductor structure, the at least one gate structure comprising a conductive material and a layer of at least one work function material present only in a limited area surrounding the at least one raised structure.

12. The non-planar semiconductor structure of claim 11, wherein a thickness of the layer of at least one work function material comprises about 1 nm to about 8 nm.

13. The non-planar semiconductor structure of claim 11, wherein the layer of at least one work function material comprises one or more p-type work function metals.

14. The non-planar semiconductor structure of claim 11, wherein the layer of at least one work function material comprises one or more n-type work function metals.

15. The non-planar semiconductor structure of claim 11, wherein the at least one raised structure comprises at least one first raised structure and at least one second raised structure, and wherein the layer of at least one work function material comprises one or more p-type work function metals for the at least one first raised structure and one or more n-type work function metals for the at least one second raised structure.

16. The non-planar semiconductor structure of claim 11, wherein the conductive material comprises a metal.

17. The non-planar semiconductor structure of claim 16 wherein the metal comprises one of tungsten and aluminum.
